(19) United States
(12) Patent Application Publication
(10) Pub. No.: US 2026/0005173 A1
(43) Pub. Date: Jan. 1, 2026

(54) EMBEDDED BRIDGE WITH PROTECTION LAYER FOR VIA FORMATION WITH BUMP PITCH SCALING

(71) Applicant: Intel Corporation, Santa Clara, CA (US)

(72) Inventors: Hiroki TANAKA, Gilbert, AZ (US); Robert Alan MAY, Chandler, AZ (US); Ching-Wei LEE, Chandler, AZ (US); Tchefor NDUKUM, Chandler, AZ (US); Deniz TURAN, Chandler, AZ (US); Vishal Bhimrao ZADE, Chandler, AZ (US); Srinivas Venkata Ramanuja PIETAMBARAM, Chandler, AZ (US); Gang DUAN, Chandler, AZ (US); Sanjay THARMARAJAH, Queen Creek, AZ (US); Suddhasattwa NAD, Chandler, AZ (US); Qiang LI, Chandler, AZ (US); Debendra MALLIK, Chandler, AZ (US)

(21) Appl. No.: 18/755,167

(22) Filed: Jun. 26, 2024

(51) Int. Cl. H01L 23/00; H01L 21/768; H01L 23/498; H01L 25/065

(52) U.S. Cl. CPC H01L 24/13; H01L 21/76898; H01L 23/49816; H01L 23/49822; H01L 24/05; H01L 25/0655; H01L 2224/05009; H01L 2224/05025; H01L 2224/13009; H01L 2224/13026; H01L 2924/01029; H01L 2924/1431; H01L 2924/1434; H01L 2924/15311

(57) ABSTRACT

Embodiments disclosed herein include an apparatus that comprises a substrate with a component in the substrate, where the component comprises a pad. In an embodiment, a first layer is over the pad, and the first layer comprises silicon and nitrogen. In an embodiment, a second layer is over the substrate, and a via that passes through the first layer and the second layer, where the via contacts the pad.

### BACKGROUND

Industry trends continue to push for further scaling of electronic packaging form factors. For example, bump pitch and via dimensions have continued to decrease in order to meet the drive to enable smaller devices. One issue with continued scaling is in the maintenance of good via integrity. Via integrity may sometimes refer to via bottom critical dimension (CD), taper angle, and cleanliness at the bottom of the via. Laser drilling operations have provided adequate control of the via bottom CD and taper angle. However, cleanliness at the bottom of the via is difficult to obtain as dimensions continue to decrease. Currently, clean via bottoms require the initial laser opening process, a wet and/or dry etching process, and copper pad surface treatment. These additional processes further complicate the fabrication process, increase costs, and extend the time needed for fabrication. Even with these extra cleaning processes, foreign material may still be present at the interface between the pad and the via. In addition, electromigration can cause significant yield loss or damages on electronic packages as scaling of bump pitch continues. As the distance between vias is reduced in future products, metal ions have a higher chance to migrate into the neighboring vias, which can create electrical shorts.

### BRIEF DESCRIPTION OF THE DRAWINGS

FIG. 1A is a cross-sectional illustration of a portion of a package substrate with an embedded component, in accordance with an embodiment.

FIG. 1B is a cross-sectional illustration of the portion of the package substrate after via openings are formed over pads of the component, in accordance with an embodiment.

FIGS. 2A-2E are cross-sectional illustrations depicting a process for forming a package substrate with an embedded component with a protective layer over the component and a portion of the package substrate, in accordance with an embodiment.

FIGS. 3A-3D are cross-sectional illustrations depicting a process for forming a package substrate with an embedded component with a protective layer over a top surface of the component, in accordance with an embodiment.

FIGS. 4A-4D are cross-sectional illustrations depicting a process for forming a package substrate with an embedded component with a protective layer over the pads of the component, in accordance with an embodiment.

FIG. 5A is a cross-sectional illustration of a portion of a package substrate with an embedded component with vias that includes a protective layer over the component and a portion of the package substrate, in accordance with an embodiment.

FIG. 5B is a cross-sectional illustration of a portion of a package substrate with an embedded component with vias that includes a protective layer over a top surface of the component, in accordance with an embodiment.

FIG. 5C is a cross-sectional illustration of a portion of a package substrate with an embedded component with vias that includes a protective layer over the pads of the component, in accordance with an embodiment.

FIG. 6 is a process flow diagram of a process for forming a package substrate with an embedded component that includes a protective layer, in accordance with an embodiment.

FIGS. 7A and 7B are cross-sectional illustrations of a portion of an electronic system that comprises a package substrate with an embedded component that includes a protective layer, in accordance with an embodiment.

FIG. 8 is a schematic of a computing device built in accordance with an embodiment.

### EMBODIMENTS OF THE PRESENT DISCLOSURE

Described herein are package architectures with embedded components that include a protective liner over pads to improve via opening cleanliness, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, forming vias that land on pads of an underlying component is becoming difficult as the critical dimension (CD) of the via continues to shrink to accommodate smaller form factors. Particularly, the cleanliness of the interface between the via bottom and the pad is difficult to control. This is due, at least in part, to the localized melting of the copper pad during via opening formation with a laser. Organic residues and fillers from the substrate may be trapped by the melted copper. The trapping of organic material and filler material is also made more problematic when the copper is roughened in order to improve adhesion strength. The resulting interface between the via and the pad may have organic regions that impact electrical conductivity between the via and the pad. This can significantly impact performance of the device.

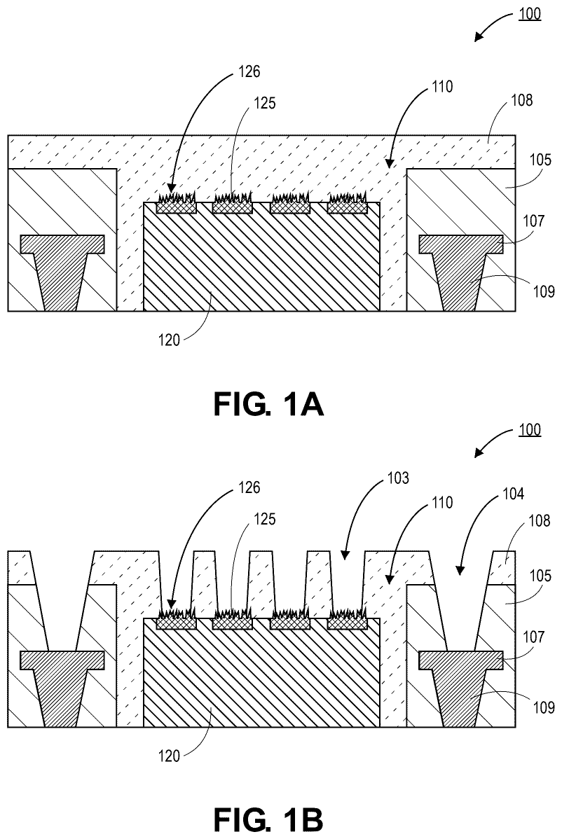

An example of such an issue is shown in FIGS. 1A and 1B. In FIG. 1A, a portion of a package substrate 100 is shown. The package substrate 100 may comprise a substrate 105 with a cavity 110. The substrate 105 may comprise electrical routing, such as pads 107, vias 109, and/or the like. A component 120 may be set into the cavity 110. An encapsulation layer 108 is provided over the substrate 105 and the component 120. While shown with different shading, it is to be appreciated that the substrate 105 and the encapsulation layer 108 may include the same material (e.g., a dielectric buildup material or the like).

As shown, the component 120 may comprise pads 125, such as copper pads. The pads 125 may have a roughened surface 126. The surface 126 may be roughened with any suitable roughening process (e.g., an etching process or the like). For example, an average surface roughness Ra of the pads 125 may be approximately 100 nm or greater. The roughened surface 126 may be beneficial to improve adhesion with the encapsulation layer 108.

Referring now to FIG. 1B, a cross-sectional illustration of the portion of the package substrate 100 is shown. In FIG. 1B, via openings 104 and 103 are formed. For example, a laser ablation process may be used in order to form the via openings 104 and 103. The via openings 104 may pass through a portion of the encapsulation layer 108 and a portion of the substrate 105 in order to expose pads 107. The via openings 103 may pass through a portion of the encapsulation layer 108 in order to expose the pads 125. As shown, the via openings 104 and 103 have tapered sidewalls, which are typical of laser ablation processes.

During the laser ablation process, organic material and/or fillers from the encapsulation layer 108 may be trapped at the roughened surface 126 of the pads 125. The organic material and/or fillers may be trapped due to localized melting of the pads 125. The roughened surface 126 can also increase the amount of foreign material that is trapped at the pad 125. As such, extensive cleaning processes may be needed before the vias are formed in the via openings 103. This cleaning process increases the cost of fabricating the package substrate 100 and lengthens the time to fabricate the package substrate 100.

Accordingly, embodiments disclosed herein may include a protective layer over the pads of the component. The protective layer shields the pads from the laser ablation process. This can prevent localized melting, and mitigates the trapping of foreign material. The protective layer may also allow for the pads to be smoother than previous solutions. For example, the protective layer may also improve adhesion in some embodiments. In an embodiment, the laser ablation process ablates the encapsulation layer, and the protective layer is exposed. A subsequent etch can be used to punch through the protective layer in order to expose the pads. The pads are cleaner since the etching process will not result in the generation of foreign material in a form that can integrated into the pads. Additionally, the pads will not undergo localized melting, so it is less likely that foreign material is trapped. In addition, electromigration (i.e., the process of metal ions moving into dielectric material under electrically biased conditions) can occur between pads 125 and eventually result in the generation of an electrical short between pads 125 as bump pitch shrinks.

In one embodiment, the protective layer is applied to the component after the component is inserted into a cavity in the package substrate. The protective layer may be blanket deposited across the package substrate. As such, the protective layer may be present over the component and over one or more surfaces of the package substrate. In another embodiment, the protective layer may be applied over the top surface of the component before the component is placed into the cavity of the package substrate. In such an embodiment, the protective layer may be provided over only the top surface of the component. In yet another embodiment, the protective layer may be selectively formed over the pads of the component. As such, the top surface of the component may be free from the protective layer, except for the pads.

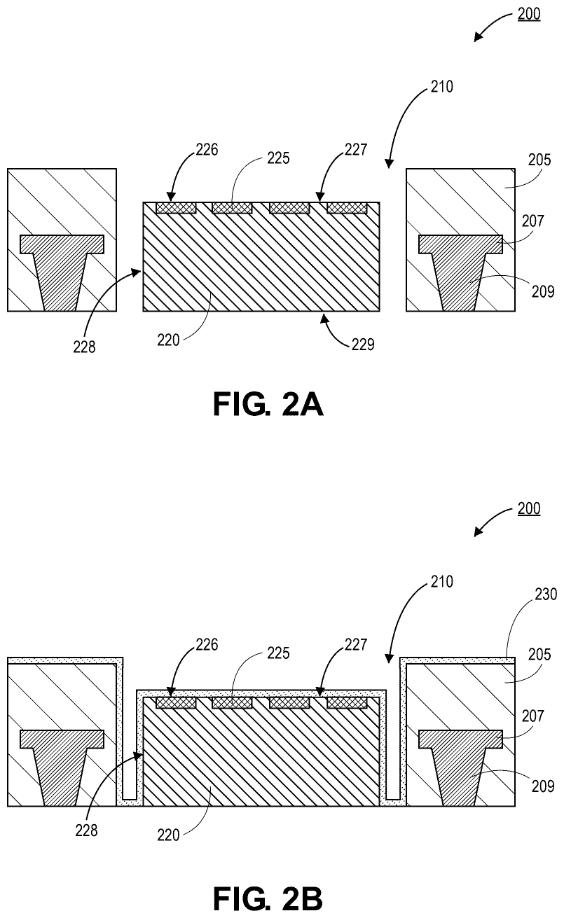

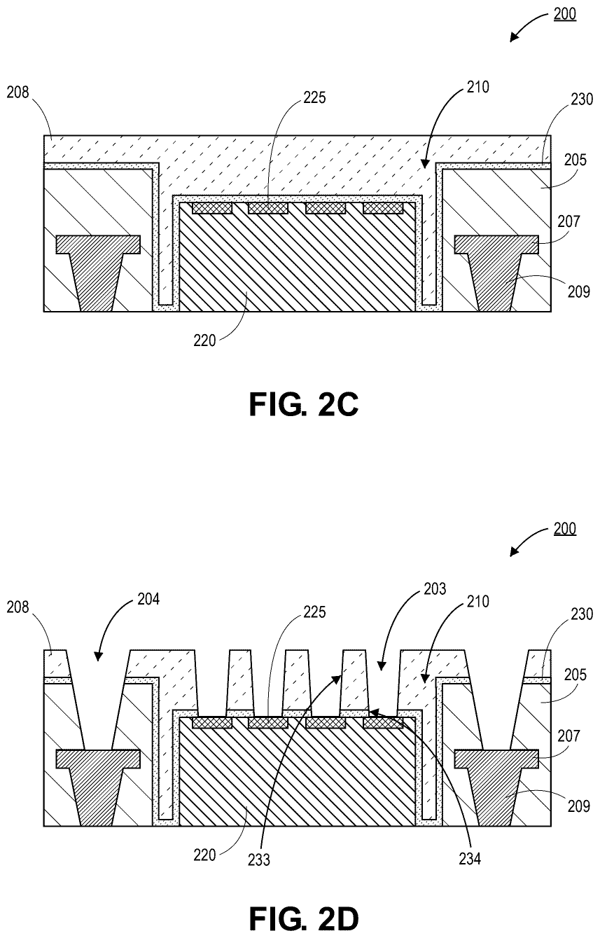

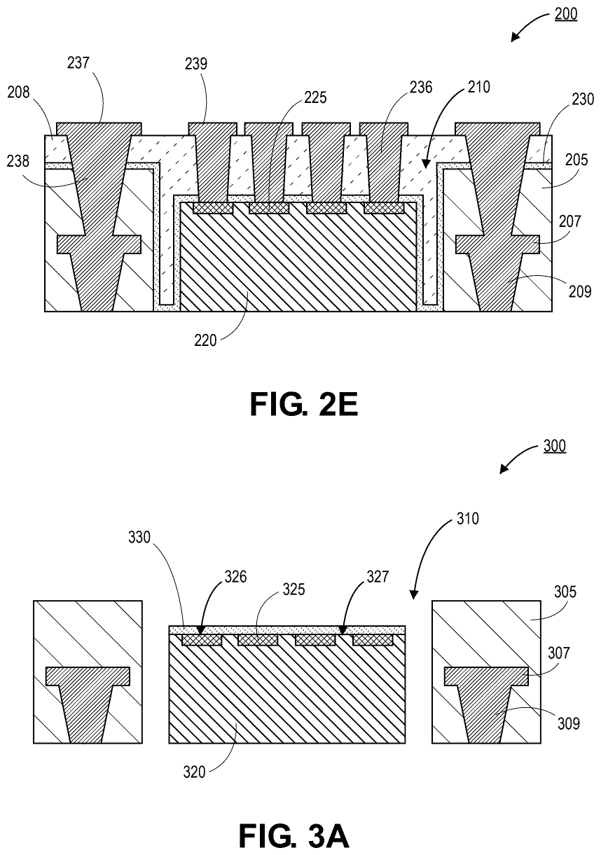

Referring now to FIGS. 2A-2E, a series of cross-sectional illustrations depicting a process for fabricating a portion of a package substrate 200 is shown, in accordance with an embodiment. In an embodiment, the package substrate 200 includes a component 220 that is set into a cavity 210 of a substrate 205. A protective layer 230 is deposited across the package substrate 200 in order to protect pads 225 of the component 220 from a laser ablation process.

Referring now to FIG. 2A, a cross-sectional illustration of the portion of the package substrate 200 is shown, in accordance with an embodiment. In an embodiment, the package substrate 200 may comprise a substrate 205. The substrate 205 may be a dielectric material, such as a buildup film. The substrate 205 may have a cavity 210 into a top surface of the substrate 205. The cavity 210 may pass partially through a thickness of the substrate 205, and a component 220 is placed at the bottom surface of the cavity 210.

For example, a bottom surface 229 of the component 220 may rest on a bottom surface of the cavity 210. In an embodiment, electrical routing, such as pads 207, vias 209, traces (not shown), and/or the like may be integrated into the substrate 205.

In an embodiment, the component 220 may be any type of device or structure. In a particular embodiment, the component 220 may be a bridge that is configured for electrically coupling a first die (not shown) to a second die (not shown). For example, pads 225 on the component 220 may be electrically coupled together by electrically conductive traces (not shown) on and/or in the component 220. In an embodiment, the component 220 may comprise any suitable material, such as silicon, glass, ceramic, organic dielectric, and/or the like. The component 220 may also comprise routing layers over the underlying component 220 substrate material.

While bridge architectures are provided as one example of a component 220, other component 220 devices may also be used. For example, the component 220 may be a passive device, such as a capacitor, an inductor, a resistor, or the like. The component 220 may also be an active device, such as a die with transistors and/or other switching structures. The component 220 may also be a combination of one or more of a bridge, a passive device, and/or an active device.

In an embodiment, the component 220 may comprise pads 225 that are provided on a top surface 227 of the component 220. For example, a surface 226 of the pads 225 may be substantially coplanar with the top surface 227. Though, the surface 226 of the pads 225 may be raised up from the top surface 227 in other embodiments. In an embodiment, the surface 226 may be a substantially smooth surface. For example, an average surface roughness (Ra) may be approximately 100 nm or less in some embodiments. The pads 225 may comprise copper (or any other suitable metal). The pads 225 may also comprise barrier layers and/or the like in some embodiments. In an embodiment, the top surface 227 of the component 220 may be coupled to the bottom surface 229 of the component 220 by sidewall surfaces 228.

Referring now to FIG. 2B, a cross-sectional illustration of the portion of the package substrate 200 after a protective layer 230 is applied is shown, in accordance with an embodiment. In an embodiment, the protective layer 230 may be applied with a blanket deposition process. For example, a chemical vapor deposition (CVD) process may be used in order to deposit the protective layer 230 across the entire surface of the package substrate 200. For example, the protective layer 230 may be provided on a top surface of the substrate 205, along sidewalls of the cavity 210, along a bottom surface of the cavity 210, along sidewall surfaces 228 of the component 220, over the top surface 227 of the component 220, and over the surface 226 of the pads 225.

In an embodiment, the protective layer 230 may be an inorganic material. In one embodiment, the protective layer 230 may comprise silicon and nitrogen (e.g., SiN) or any other metal oxides (e.g., SiO₂, SiOₓN_{y}, SiC, Al₂O₃, TiO₂, ZrO₂, CrₓO_{y}, NbO₂, BaTiO₃, SrTiO₃, or other mixed-metal oxides (e.g., BiₓTi_{y}W_{z}O_{q})). The protective layer 230 may provide multiple benefits to the package substrate 200. As noted above, the protective layer 230 may be used to reduce the integration of foreign material into the surface 226 of the pads 225 during via opening processes. The protective layer 230 can also be an adhesion promoting surface between the component 220 and a subsequently added encapsulation layer. In yet another embodiment, the protective layer 230 can function as a copper migration barrier. This can mitigate the migration of copper between pads 225, which may otherwise result in electrical shorting between pads 225. As the pitch between pads 225 continues to decrease, such copper mitigation properties become more important for device reliability.

Referring now to FIG. 2C, a cross-sectional illustration of the portion of the package substrate 200 after an encapsulation layer 208 is applied is shown, in accordance with an embodiment. In the illustrated embodiment, the encapsulation layer 208 has a different shading than the substrate 205. However, the encapsulation layer 208 and the substrate 205 may comprise the same material or a similar material in some embodiments. For example, the encapsulation layer 208 may comprise a buildup film or the like. The encapsulation layer 208 may be provided over the substrate 205 and the component 220 with a lamination process or the like. The encapsulation layer 208 may fill a portion of the cavity 210 that is not occupied by the component 220.

In an embodiment, the encapsulation layer 208 may be in direct contact with the protective layer 230. As noted above, the protective layer 230 may improve adhesion of the encapsulation layer 208 to the component 220 and/or the substrate 205. As illustrated, the protective layer 230 may directly contact the substrate 205 along a bottom surface and directly contact the encapsulation layer 208 along a top surface. In the case where the encapsulation layer 208 and the substrate 205 are the same or similar material, the protective layer 230 may provide a visible delineation between the substrate 205 and the encapsulation layer 208.

Referring now to FIG. 2D, a cross-sectional illustration of the portion of the package substrate 200 after via openings 203 and 204 are formed is shown, in accordance with an embodiment. In an embodiment, the via openings 204 may pass through a portion of the encapsulation layer 208, the protective layer 230, and a portion of the substrate 205. The via openings 204 may expose pads 207. The via openings 204 may be formed with a laser ablation process. In an embodiment, the via openings 203 may pass through a portion of the encapsulation layer 208 and the protective layer 230. The via openings 203 may expose the pads 225 of the component 220. In an embodiment, the via openings 203 may be formed, at least in part, with a laser ablation process. For example, the portion of the via openings 203 through the encapsulation layer 208 may be formed with the laser ablation process. The protective layer 230 may protect the pads 225 from the laser ablation. In an embodiment, the protective layer 230 may be removed by a non-laser process. For example, an etching process, a desmear process, or the like may be used to pass through the protective layer 230 without significantly altering the pads 225.

In an embodiment, the process for forming the via openings 203 may result in the formation of via openings 203 that have a unique profile. For example, a first sidewall portion 233 through the encapsulation layer 208 may have tapered sidewalls typical of laser ablation processes. A second sidewall portion 234 through the protective layer 230 may be substantially vertical (e.g., between approximately eighty degrees and approximately ninety degrees relative to a top surface of the substrate 205). Stated differently, an angle of the first sidewall portion 233 relative to the top surface of the substrate 205 may be different than an angle of the second sidewall portion 234 relative to the top surface of the substrate 205. Though, in other embodiments, the via openings 203 may have a substantially continuous sidewall profile from top to bottom. In some instances, the presence of the sidewall 234 may minimize and/or prevent electromigration between pads 225.

Referring now to FIG. 2E, a cross-sectional illustration of the portion of the package substrate 200 after vias 238 and 236 are formed in the via openings 204 and 203, respectively, is shown, in accordance with an embodiment. As shown, vias 238 are provided in via openings 204 in order to electrically couple pads 207 to pads 237. Vias 236 are provided in via openings 203 in order to electrically couple pads 225 of the component 220 to pads 239. Due to the shape of the via openings 203, the sidewalls of the vias 236 may also have a first portion and a second portion with different angles relative to the top surface of the substrate 205. In an embodiment, the vias 238 and 236 and the pads 237 and 239 may be formed with any suitable plating process. For example, an electroplating process or the like may be used in order to form the electrical features.

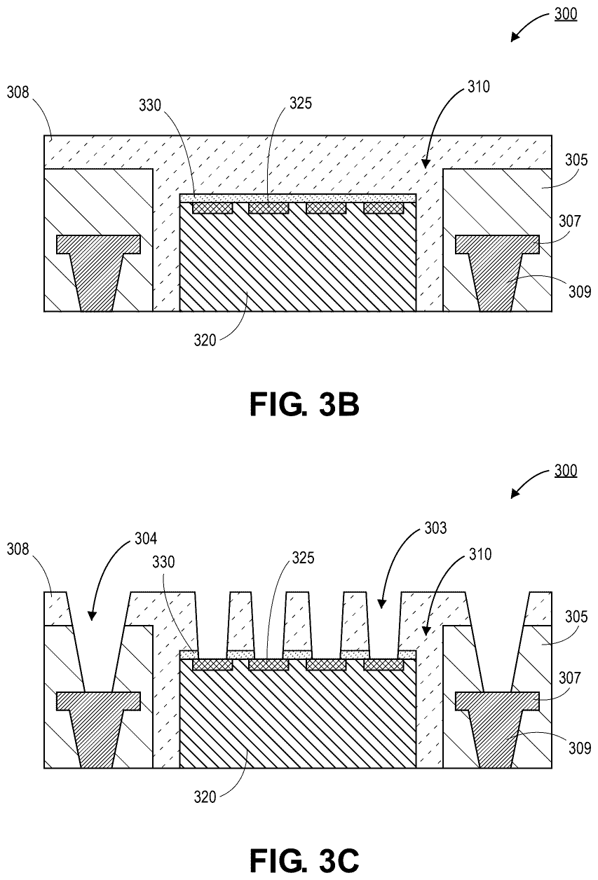

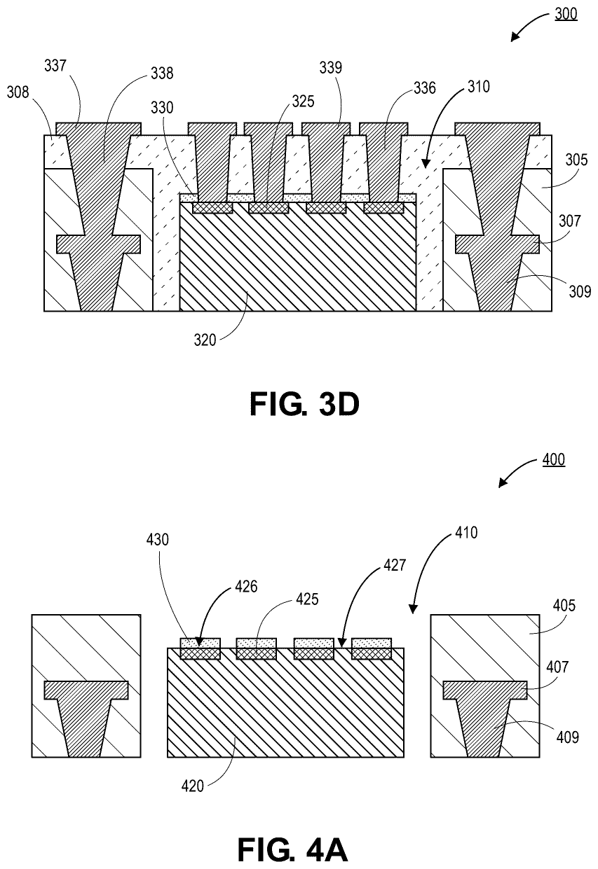

Referring now to FIGS. 3A-3D, a series of cross-sectional illustrations depicting a process for fabricating a portion of a package substrate 300 is shown, in accordance with an embodiment. In an embodiment, the package substrate 300 includes a component 320 that is set into a cavity 310 of a substrate 305. A protective layer 330 is deposited across the component 320 in order to protect pads 325 of the component 320 from a laser ablation process.

Referring now to FIG. 3A, a cross-sectional illustration of the portion of the package substrate 300 is shown, in accordance with an embodiment. In an embodiment, the package substrate 300 may comprise a substrate 305. The substrate 305 may be a dielectric material, such as a buildup film. The substrate 305 may have a cavity 310 into a top surface of the substrate 305. The cavity 310 may pass partially through a thickness of the substrate 305, and a component 320 is placed at the bottom surface of the cavity 310, similar to the embodiment described above with respect to FIG. 2A. In an embodiment, electrical routing, such as pads 307, vias 309, traces (not shown), and/or the like may be integrated into the substrate 305.

In an embodiment, the component 320 may be any type of device or structure. In a particular embodiment, the component 320 may be a bridge that is configured for electrically coupling a first die (not shown) to a second die (not shown), similar to any of the bridge structures described in greater detail herein. In an embodiment, the component 320 may also comprise a passive device, an active device, or a combination of one or more of a passive device, an active device, and/or a bridge, similar to any of the other components described in greater detail herein.

In an embodiment, the component 320 may comprise pads 325 that are provided on a top surface 327 of the component 320. For example, a surface 326 of the pads 325 may be substantially coplanar with the top surface 327. Though, the surface 326 of the pads 325 may be raised up from the top surface 327 in other embodiments. In an embodiment, the surface 326 may be a substantially smooth surface. For example, an average surface roughness (Ra) may be approximately 100 nm or less in some embodiments. The pads 325 may comprise copper. The pads 325 may also comprise barrier layers and/or the like in some embodiments.

In an embodiment, a protective layer 330 is provided over the top surface 327 of the component 320. The protective layer 330 may also be provided over the surface 326 of the pads 325. As such, the protective layer 330 may protect the pads 325 from laser exposure during via opening formation. In an embodiment, the protective layer 330 may be provided on the component 320 before the component 320 is inserted into the cavity 310. As such, a distinct protective layer 330 deposition process may not be needed in some embodiments. In an embodiment, the protective layer 330 may be similar to any of the protective layers described in greater detail herein. For example, the protective layer 330 may comprise silicon and nitrogen (e.g., SiN) or any other metal oxides (e.g., SiO₂, SiOₓN_{y}, SiC, Al₂O₃, TiO₂, ZrO₂, CrₓO_{y}, NbO₂, BaTiO₃, SrTiO₃, or other mixed-metal oxides (e.g., BiₓTi_{y}W_{z}O_{q})).

Referring now to FIG. 3B, a cross-sectional illustration of the portion of the package substrate 300 after an encapsulation layer 308 is applied is shown, in accordance with an embodiment. In the illustrated embodiment, the encapsulation layer 308 has a different shading than the substrate 305. However, the encapsulation layer 308 and the substrate 305 may comprise the same material or a similar material in some embodiments. For example, the encapsulation layer 308 may comprise a buildup film or the like. The encapsulation layer 308 may be provided over the substrate 305 and the component 320 with a lamination process or the like. The encapsulation layer 308 may fill a portion of the cavity 310 that is not occupied by the component 320. In an embodiment, the encapsulation layer 308 may be in direct contact with the protective layer 330. As noted above, the protective layer 330 may improve adhesion of the encapsulation layer 308 to the component 320.

Referring now to FIG. 3C, a cross-sectional illustration of the portion of the package substrate 300 after via openings 303 and 304 are formed is shown, in accordance with an embodiment. In an embodiment, the via openings 304 may pass through a portion of the encapsulation layer 308 and a portion of the substrate 305. The via openings 304 may expose pads 307. The via openings 304 may be formed with a laser ablation process. In an embodiment, the via openings 303 may pass through a portion of the encapsulation layer 308 and the protective layer 330. The via openings 303 may expose the pads 325 of the component 320. In an embodiment, the via openings 303 may be formed, at least in part, with a laser ablation process. For example, the portion of the via openings 303 through the encapsulation layer 308 may be formed with the laser ablation process. The protective layer 330 may protect the pads 325 from the laser ablation. In an embodiment, the protective layer 330 may be removed by a non-laser process. For example, an etching process, a desmear process, or the like may be used to pass through the protective layer 330 without significantly altering the pads 325. In some embodiments, the residual presence of the protective layer 330 at the bottom of the via opening and between the pads 325 can mitigate and/or prevent electromigration between pads 325.

In an embodiment, the process for forming the via openings 303 may result in the formation of via openings 303 that have a unique profile, similar to the profile of via openings 203 described in greater detail herein. For example, the via openings 303 may have a tapered sidewall portion through the encapsulation layer 308 and a substantially vertical portion through the protective layer 330. More generally, an angle of the sidewall portion through the encapsulation layer 308 relative to a top surface of the substrate 305 is different than an angle of the sidewall portion through the protective layer 330 relative to the top surface of the substrate 305.

Referring now to FIG. 3D, a cross-sectional illustration of the portion of the package substrate 300 after vias 338 and 336 are formed in the via openings 304 and 303, respectively, is shown, in accordance with an embodiment. As shown, vias 338 are provided in via openings 304 in order to electrically couple pads 307 to pads 337. Vias 336 are provided in via openings 303 in order to electrically couple pads 325 of the component 320 to pads 339. Due to the shape of the via openings 303, the sidewalls of the vias 336 may also have a first portion and a second portion with different angles relative to the top surface of the substrate 305. In an embodiment, the vias 338 and 336 and the pads 337 and 339 may be formed with any suitable plating process. For example, an electroplating process or the like may be used in order to form the electrical features.

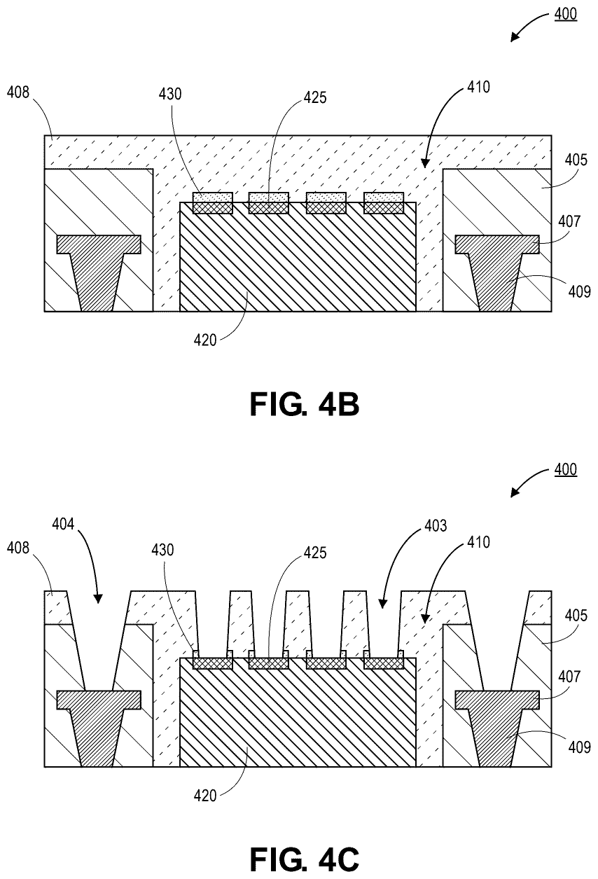

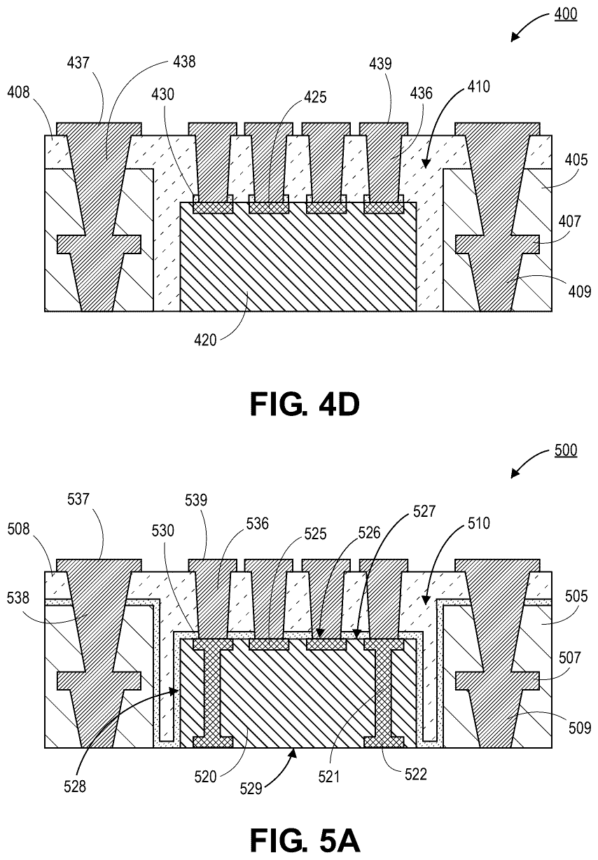

Referring now to FIGS. 4A-4D, a series of cross-sectional illustrations depicting a process for fabricating a portion of a package substrate 400 is shown, in accordance with an embodiment. In an embodiment, the package substrate 400 includes a component 420 that is set into a cavity 410 of a substrate 405. A protective layer 430 is deposited on the pads 425 of component 420 in order to protect pads 425 of the component 420 from a laser ablation process.

Referring now to FIG. 4A, a cross-sectional illustration of the portion of the package substrate 400 is shown, in accordance with an embodiment. In an embodiment, the package substrate 400 may comprise a substrate 405. The substrate 405 may be a dielectric material, such as a buildup film. The substrate 405 may have a cavity 410 into a top surface of the substrate 405. The cavity 410 may pass partially through a thickness of the substrate 405, and a component 420 is placed at the bottom surface of the cavity 410, similar to the embodiment described above with respect to FIG. 2A. In an embodiment, electrical routing, such as pads 407, vias 409, traces (not shown), and/or the like may be integrated into the substrate 405.

In an embodiment, the component 420 may be any type of device or structure. In a particular embodiment, the component 420 may be a bridge that is configured for electrically coupling a first die (not shown) to a second die (not shown), similar to any of the bridge structures described in greater detail herein. In an embodiment, the component 420 may also comprise a passive device, an active device, or a combination of one or more of a passive device, an active device, and/or a bridge, similar to any of the other components described in greater detail herein.

In an embodiment, the component 420 may comprise pads 425 that are provided on a top surface 427 of the component 420. For example, a surface 426 of the pads 425 may be substantially coplanar with the top surface 427. Though, the surface 426 of the pads 425 may be raised up from the top surface 427 in other embodiments. In an embodiment, the surface 426 may be a substantially smooth surface. For example, an average surface roughness (Ra) may be approximately 100 nm or less in some embodiments. The pads 425 may comprise copper. The pads 425 may also comprise barrier layers and/or the like in some embodiments.

In an embodiment, a protective layer 430 is provided over the top surface 426 of the pads 425. As such, the protective layer 430 may protect the pads 425 from laser exposure during via opening formation. The protective layer 430 may be selectively formed on the pads 425 so that a top surface 427 of the component 420 is exposed. In an embodiment, the protective layer 430 may be provided on the pads 425 before the component 420 is inserted into the cavity 410. As such, a distinct protective layer 430 deposition process may not be needed in some embodiments. In an embodiment, the protective layer 430 may be similar to any of the protective layers described in greater detail herein. For example, the protective layer 430 may comprise silicon and nitrogen (e.g., SiN) or any other metal oxides (e.g., SiO₂, SiOₓN_{y}, SiC, Al₂O₃, TiO₂, ZrO₂, CrₓO_{y}, NbO₂, BaTiO₃, SrTiO₃, or other mixed-metal oxides (e.g., BiₓTi_{y}W_{z}O_{q})).

Referring now to FIG. 4B, a cross-sectional illustration of the portion of the package substrate 400 after an encapsulation layer 408 is applied is shown, in accordance with an embodiment. In the illustrated embodiment, the encapsulation layer 408 has a different shading than the substrate 405. However, the encapsulation layer 408 and the substrate 405 may comprise the same material or a similar material in some embodiments. For example, the encapsulation layer 408 may comprise a buildup film or the like. The encapsulation layer 408 may be provided over the substrate 405 and the component 420 with a lamination process or the like. The encapsulation layer 408 may fill a portion of the cavity 410 that is not occupied by the component 420. In an embodiment, the encapsulation layer 408 may be in direct contact with the protective layer 430. As noted above, the protective layer 430 may improve adhesion of the encapsulation layer 408 to the component 420.

Referring now to FIG. 4C, a cross-sectional illustration of the portion of the package substrate 400 after via openings 403 and 404 are formed is shown, in accordance with an embodiment. In an embodiment, the via openings 404 may pass through a portion of the encapsulation layer 408 and a portion of the substrate 405. The via openings 404 may expose pads 407. The via openings 404 may be formed with a laser ablation process. In an embodiment, the via openings 403 may pass through a portion of the encapsulation layer 408 and the protective layer 430. The via openings 403 may expose the pads 425 of the component 420. In an embodiment, the via openings 403 may be formed, at least in part, with a laser ablation process. For example, the portion of the via openings 403 through the encapsulation layer 408 may be formed with the laser ablation process. The protective layer 430 may protect the pads 425 from the laser ablation. In an embodiment, the protective layer 430 may be removed by a non-laser process. For example, an etching process, a desmear process, or the like may be used to pass through the protective layer 430 without significantly altering the pads 425. As shown, a portion of the protective layer 430 may persist over regions of the pads 425 that are not exposed by the via openings 403. In some embodiments, the residual presence of the protective layer 430 at the bottom of the via opening and between the pads 425 can mitigate and/or prevent electromigration between pads 425.

In an embodiment, the process for forming the via openings 403 may result in the formation of via openings 403 that have a unique profile, similar to the profile of via openings 203 described in greater detail herein. For example, the via openings 403 may have a tapered sidewall portion through the encapsulation layer 408 and a substantially vertical portion through the protective layer 430. More generally, an angle of the sidewall portion through the encapsulation layer 408 relative to a top surface of the substrate 405 is different than an angle of the sidewall portion through the protective layer 430 relative to the top surface of the substrate 405.

Referring now to FIG. 4D, a cross-sectional illustration of the portion of the package substrate 400 after vias 438 and 436 are formed in the via openings 404 and 403, respectively, is shown, in accordance with an embodiment. As shown, vias 438 are provided in via openings 404 in order to electrically couple pads 407 to pads 437. Vias 436 are provided in via openings 403 in order to electrically couple pads 425 of the component 420 to pads 439. Due to the shape of the via openings 403, the sidewalls of the vias 436 may also have a first portion and a second portion with different angles relative to the top surface of the substrate 405. In an embodiment, the vias 438 and 436 and the pads 437 and 439 may be formed with any suitable plating process. For example, an electroplating process or the like may be used in order to form the electrical features.

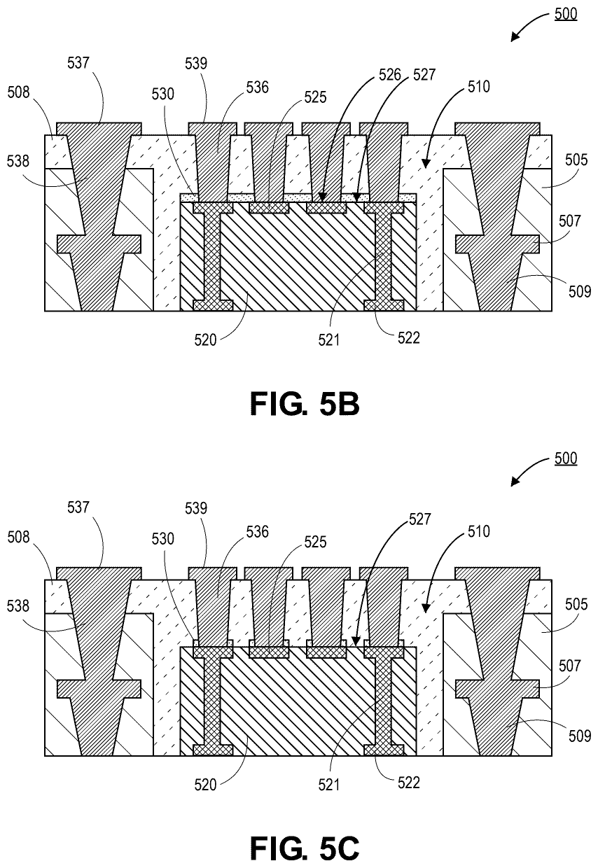

Referring now to FIGS. 5A-5C, a series of cross-sectional illustrations of a portion of a package substrate 500 is shown, in accordance with an embodiment. In an embodiment, the package substrates 500 may be similar to some of the package substrates described in greater detail herein, with the exception of the embedded components 520. For example, vias 521 and bottom pads 522 may be added to the component 520. This may allow for power and/or signals to be passed vertically through a thickness of the component 520.

Referring now to FIG. 5A, a cross-sectional illustration of a portion of a package substrate 500 is shown, in accordance with an embodiment. In an embodiment, the package substrate 500 may comprise a substrate 505. The substrate 505 may be a dielectric material, such as a buildup film. The substrate 505 may have a cavity 510 into a top surface of the substrate 505. The cavity 510 may pass partially through a thickness of the substrate 505, and a bottom surface 529 of the component 520 is placed at the bottom surface of the cavity 510, similar to the embodiment described above with respect to FIG. 2A. In an embodiment, electrical routing, such as pads 507, vias 509, traces (not shown), and/or the like may be integrated into the substrate 505.

In an embodiment, the component 520 may be any type of device or structure. In a particular embodiment, the component 520 may be a bridge that is configured for electrically coupling a first die (not shown) to a second die (not shown), similar to any of the bridge structures described in greater detail herein. In an embodiment, the component 520 may also comprise a passive device, an active device, or a combination of one or more of a passive device, an active device, and/or a bridge, similar to any of the other components described in greater detail herein. As noted above, the component 520 may also comprise one or more vias 521 that pass at least partially through a thickness of the component 520. The vias 521 may electrically couple pads 525 on a top surface 527 of the component 520 to pads 522 on a bottom surface 529 of the component 520. In an embodiment, the surface 526 may be a substantially smooth surface. For example, an average surface roughness (Ra) may be approximately 100 nm or less in some embodiments. The pads 525 may comprise copper. The pads 525 may also comprise barrier layers and/or the like in some embodiments.

In an embodiment, a protective layer 530 is provided across the package substrate 500. For example, the protective layer 530 may be provided on the substrate 505, along sidewalls of the cavity 510, along sidewalls 528 of the component 520, and along the top surface 527 of the component 520. The protective layer 530 may also cover the surface of the pads 525. As such, the protective layer 530 may protect the pads 525 from laser exposure during via opening formation. In addition, residual protective layer 530 between pads 525 may mitigate and/or prevent electromigration between pads 525. In an embodiment, the protective layer 530 may be similar to any of the protective layers described in greater detail herein. For example, the protective layer 530 may comprise silicon and nitrogen (e.g., SiN) or any other metal oxides (e.g., SiO₂, SiOₓN_{y}, SiC, Al₂O₃, TiO₂, ZrO₂, CrₓO_{y}, NbO₂, BaTiO₃, SrTiO₃, or other mixed-metal oxides (e.g., BiₓTi_{y}W_{z}O_{q})).

In an embodiment, an encapsulation layer 508 may be provided over the substrate 505 and the component 520. The encapsulation layer 508 may fill at least a portion of the cavity 510 that is not occupied by the component 520. In an embodiment, the encapsulation layer 508 may be the same material or a similar material as the substrate 505. In an embodiment, vias 536 pass through a portion of the encapsulation layer 508 and the protective layer 530 to electrically couple pads 539 to pads 525 of the component 520. Vias 538 may pass through a portion of the encapsulation layer 508, the protective layer 530, and a portion of the substrate 505 to electrically couple the pads 507 to the pads 537.

In an embodiment, the package substrate 500 in FIG. 5A may be fabricated with a process similar to the process described with respect to FIGS. 2A-2E described in greater detail herein. However, the component 520 with vias 521 replaces the component 220 without vias. In an embodiment, the overall structure of the package substrate 500 in FIG. 5A may be similar to the overall structure of the package substrate 200 in FIG. 2E, with the exception of the different structures for the components 220 and 520.

Referring now to FIG. 5B, a cross-sectional illustration of a portion of a portion of a package substrate 500 is shown, in accordance with an embodiment. In an embodiment, the package substrate 500 in FIG. 5B is similar to the package substrate 500 in FIG. 5A, with the exception of the protective layer 530. In FIG. 5B, the protective layer 530 is provided only over the component 520. That is, the protective layer 530 is provided on the top surface 527 of the component 520 and on the pads 525.

In an embodiment, the package substrate 500 in FIG. 5B may be fabricated with a process similar to the process described with respect to FIGS. 3A-3D described in greater detail herein. However, the component 520 with vias 521 replaces the component 320 without vias. In an embodiment, the overall structure of the package substrate 500 in FIG. 5B may be similar to the overall structure of the package substrate 300 in FIG. 3D, with the exception of the different structures for the components 320 and 520.

Referring now to FIG. 5C, a cross-sectional illustration of a portion of a portion of a package substrate 500 is shown, in accordance with an embodiment. In an embodiment, the package substrate 500 in FIG. 5C is similar to the package substrate 500 in FIG. 5B, with the exception of the protective layer 530. In FIG. 5C, the protective layer 530 is provided only over the pads 525 of the component 520. That is, the top surface 527 of the component 520 is directly contacted by the encapsulation layer 508.

In an embodiment, the package substrate 500 in FIG. 5C may be fabricated with a process similar to the process described with respect to FIGS. 4A-4D described in greater detail herein. However, the component 520 with vias 521 replaces the component 420 without vias. In an embodiment, the overall structure of the package substrate 500 in FIG. 5C may be similar to the overall structure of the package substrate 400 in FIG. 4D, with the exception of the different structures for the components 420 and 520.

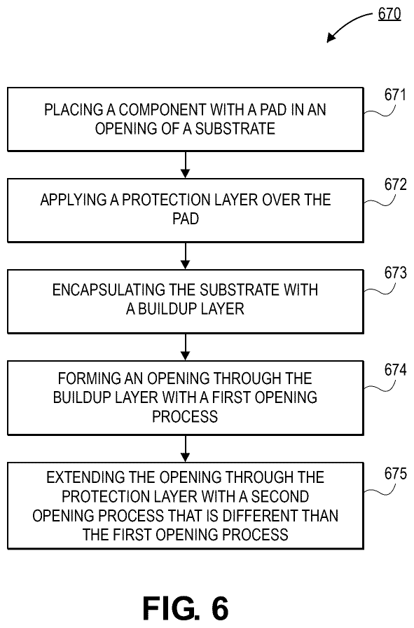

Referring now to FIG. 6, a process flow diagram of a process 670 for fabricating a package substrate with a protective layer over an embedded component is shown, in accordance with an embodiment. In an embodiment, the package substrate may be similar to any of the package substrates described in greater detail herein. The process 670 may include operations similar to any of the process flows described in greater detail herein (e.g., the process in FIGS. 2A-2E, FIGS. 3A-3D, and/or FIGS. 4A-4D).

In an embodiment, the process 670 may begin with operation 671, which comprises placing a component with a pad in an opening of a substrate. The opening may be similar to any of the cavities described in greater detail herein. Additionally, the component may be similar to any of the components described in greater detail herein. For example, the component may comprise a bridge, a passive device, an active device, or a combination thereof.

In an embodiment, the process 670 may continue with operation 672, which comprises applying a protection layer over the pad. In an embodiment, the protection layer may be similar to any of the protective layers described in greater detail herein. For example, the protection layer may comprise silicon and nitrogen (e.g., SiN) or any other metal oxides (e.g., SiO₂, SiOₓN_{y}, SiC, Al₂O₃, TiO₂, ZrO₂, CrₓO_{y}, NbO₂, BaTiO₃, SrTiO₃, or other mixed-metal oxides (e.g., BiₓTi_{y}W_{z}O_{q})). The protection layer may be applied over the entire package substrate, so that the protection layer is on the pads of the component, on a top surface of the component, on sidewalls of the component, on sidewalls of the opening, and on a surface of the substrate. In other embodiments, the protection layer may be provided only over the top surface of the component and over the pads of the component. In yet another embodiment, the protection layer may be provided only over the pads of the component. In the instances of the protection layer being only on the component (e.g., the top surface and the pads, or only the pads), the protection layer may be applied to the component before the component is inserted into the opening.

In an embodiment, the process 670 may continue with operation 673, which comprises encapsulating the substrate with a buildup layer. The buildup layer may be similar to any of the encapsulation layers described in greater detail herein. In an embodiment, the buildup layer may be applied with a lamination process or the like.

In an embodiment, the process 670 may continue with operation 674, which comprises forming an opening through the buildup layer with a first opening process. In an embodiment, the first opening process may be a laser ablation process. The protection layer over the pad may protect the pad from laser exposure during the first opening process.

In an embodiment, the process 670 may continue with operation 675, which comprises extending the opening through the protection layer with a second opening process that is different than the first opening process. In an embodiment, the second opening process may be an etching process, a desmear process (e.g., a dry desmear process), or the like. The completed opening may expose at least a portion of the pad of the component. The dual operation opening process may result in an opening with a first portion with a first angle relative to a surface of the substrate and a second portion with a second angle relative to the surface of the substrate. The second angle may be vertical (e.g., between approximately eighty degrees and approximately ninety degrees relative to the surface of the substrate).

After the opening is formed, a via may be formed in the opening. For example, a plating process may be used to deposit an electrically conductive material (e.g., copper) in order to provide an electrical connection through the encapsulation layer to the pad of the component.

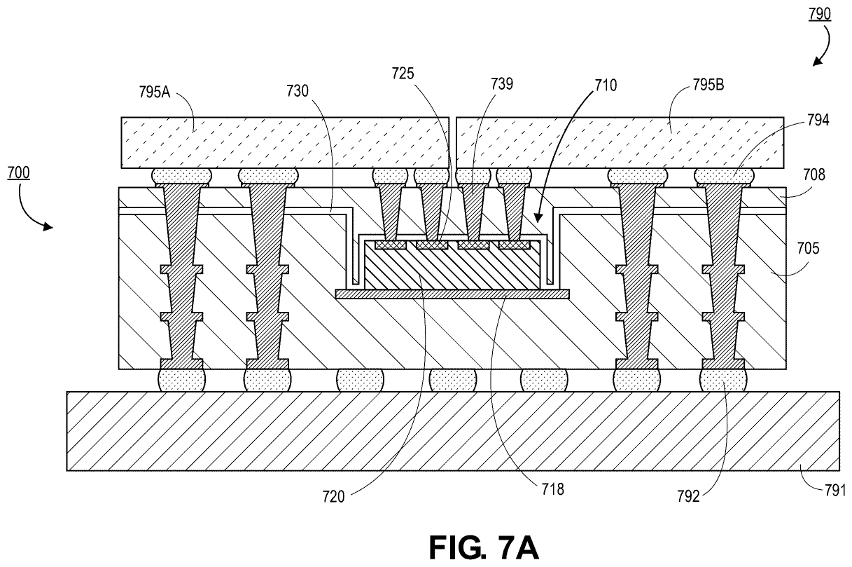

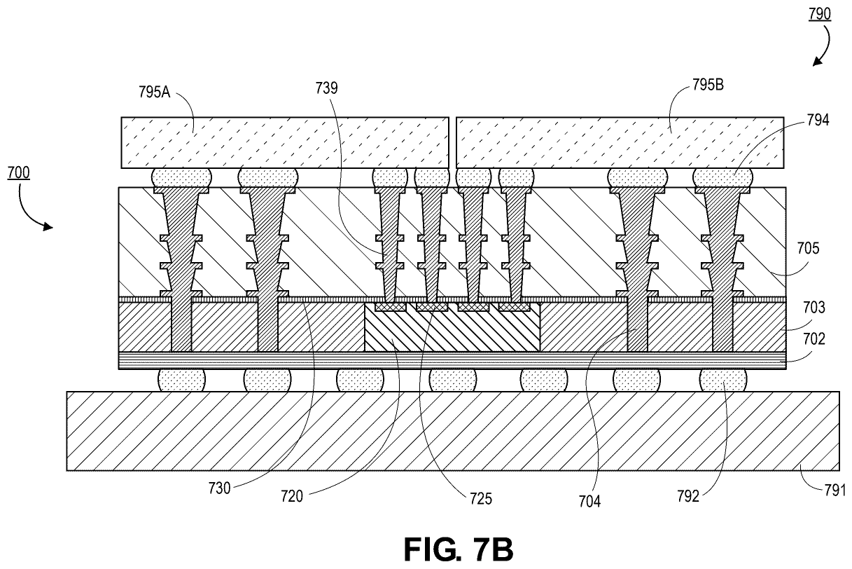

Referring now to FIG. 7A, a cross-sectional illustration of an electronic system 790 is shown, in accordance with an embodiment. In an embodiment, the electronic system 790 may comprise a board 791, such as a printed circuit board (PCB), a motherboard, or the like. The board 791 may be coupled to a package substrate 700 by interconnects 792. The interconnects 792 may comprise any suitable second level interconnect (SLI) architecture, such as solder bumps, sockets, or the like.

In an embodiment, the package substrate 700 may be similar to any of the package substrates described in greater detail herein. For example, the package substrate 700 may comprise a substrate 705 with a cavity 710. The substrate 705 may include a core (not shown), such as an organic core, a glass core, or the like. In an embodiment, the bottom of the cavity 710 may be provided by an etchstop layer 718. Though, other embodiments may omit an etchstop layer 718. In an embodiment, a component 720 may be provided in the cavity 710. The component 720 may be similar to any of the components described in greater detail herein. In an embodiment, the component 720 may comprise pads 725.

In an embodiment, a protective layer 730 may be provided over the component 720. The protective layer 730 may be provided on the pads 725, a top surface of the component 720, sidewalls of the component 720, along the bottom of the cavity 710, along sidewalls of the cavity 710, and along a horizontal portion of the substrate 705. Though, in other embodiments, the protective layer 730 may be provided over only the pads 725 and the top surface of the component 720, or only over the pads 725. The component 720 may include vias (not shown) through at least a portion of a thickness of the component 720.

In an embodiment, an encapsulation layer 708 may be provided over the component 720 and the substrate 705. The encapsulation layer 708 may fill at least a portion of the cavity 710 in some embodiments. In an embodiment, vias 739 may pass through a portion of the encapsulation layer 708 and the protective layer 730. The vias 739 may electrically couple the component 720 to a first die 795A and a second die 795B. In an embodiment, the component 720 may be a bridge that electrically couples the first die 795A to the second die 795B.

In an embodiment, the first die 795A and the second die 795B may be electrically coupled to the package substrate 700 by interconnects 794. The interconnects 794 may comprise any suitable first level interconnect (FLI) architecture, such as solder balls, copper bumps, hybrid bonding, or the like. In an embodiment, the first die 795A and the second die 795B may comprise any suitable type of die, such as a central processing unit (CPU), a graphics processing unit (GPU), an XPU, an application specific integrated circuit (ASIC), a field programmable gate array (FPGA), a communications die, a memory die, and/or the like.

Referring now to FIG. 7B, a cross-sectional illustration of an electronic system 790 is shown, in accordance with an embodiment. In an embodiment, the electronic system 790 in FIG. 7B is similar to electronic system 790 in FIG. 7A, with the exception of the package substrate 700. In an embodiment, the component 720 with pads 725 is embedded in a dielectric layer 703 (e.g., a mold layer, an epoxy, a buildup film, etc.). The dielectric layer 703 may also comprise vias 704, such as copper pillars that extend up from a first redistribution layer 702. In an embodiment, the protective layer 730 may extend over the dielectric layer 703, the component 720, and the pads 725. Though, in other embodiments, the protective layer 730 may be provided over only the pads 725 and the top surface of the component 720, or only over the pads 725. In an embodiment, an additional layer 705 (e.g., one or more buildup layers or second redistribution layers) may be provided over the dielectric layer 703 and the component 720. The vias 739 may pass through the additional layer 705 to electrically couple the dies 795A and 795B to the pads 725 of the component 720.

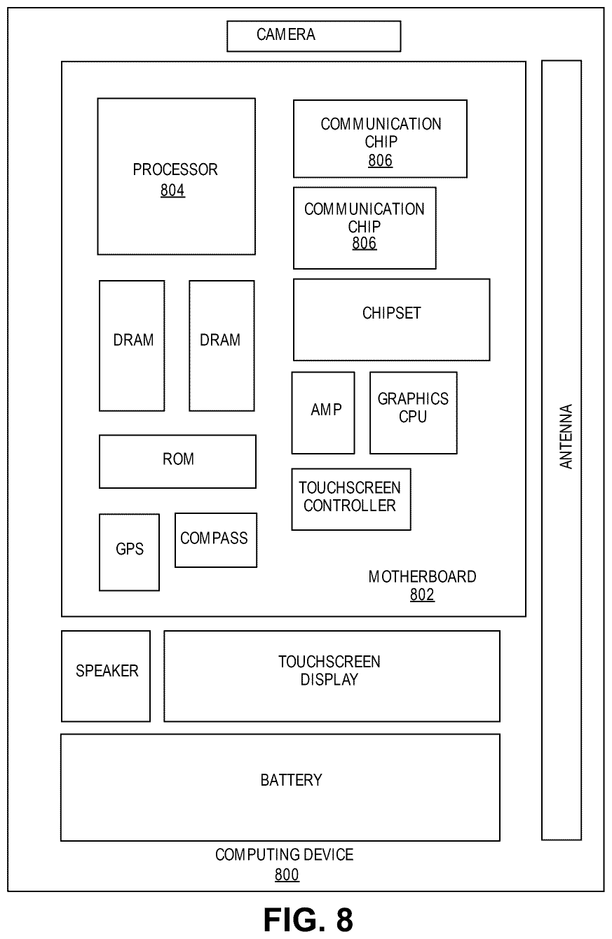

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that comprises a package substrate with an embedded component that is protected by a protective layer, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that comprises a package substrate with an embedded component that is protected by a protective layer, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate; a component in the substrate, wherein the component comprises a pad; a first layer over the pad, wherein the first layer comprises silicon and nitrogen; a second layer over the substrate; and a via that passes through the first layer and the second layer, wherein the via contacts the pad.

Example 2: the apparatus of Example 1, wherein the first layer only contacts the component at the pad.

Example 3: the apparatus of Example 1, wherein the first layer contacts a surface of the component and the pad.

Example 4: the apparatus of Example 1 or Example 3, wherein the first layer contacts a surface of the component, the pad, and a sidewall of the component.

Example 5: the apparatus of Example 4, wherein the first layer contacts the substrate.

Example 6: the apparatus of Examples 1-5, further comprising a cavity in the substrate, wherein the component is within the cavity, and wherein the second layer fills a portion of the cavity and contacts the first layer.

Example 7: the apparatus of Examples 1-6, wherein the component is a bridge configured to provide an electrical connection between a first die and a second die over the substrate.

Example 8: the apparatus of Examples 1-7, wherein the component comprises a via through at least a portion of a thickness of the component.

Example 9: the apparatus of Examples 1-8, wherein the component comprises a glass layer, a dielectric layer, a ceramic layer, or a layer comprising silicon.

Example 10: the apparatus of Examples 1-9, wherein the substrate is electrically coupled to a board, and wherein the component is electrically coupled to a first die and a second die.

Example 11: an apparatus, comprising: a substrate with a first surface and a second surface opposite from the first surface; a cavity into the first surface; a component in the cavity, wherein the component comprises a pad; a first layer over the component, wherein the first layer contacts at least a portion of the pad; a second layer over the substrate, wherein the second layer covers the component and fills a portion of the cavity; and a via through the second layer and the first layer, wherein the via contacts the pad, and wherein the via has a first sidewall with a first angle relative to the first surface of the substrate and a second sidewall with a second angle relative to the first surface of the substrate.

Example 12: the apparatus of Example 11, wherein the first angle is between approximately 80° and approximately 90°, and wherein the first sidewall is through a thickness of the first layer.

Example 13: the apparatus of Example 11 or Example 12, wherein the pad has an average surface roughness (Ra) that is approximately 100 nm or greater.

Example 14: the apparatus of Examples 11-13, wherein the first layer contacts the pad and a surface of the component adjacent to the pad.

Example 15: the apparatus of Example 14, wherein the first layer further contacts a sidewall of the component.

Example 16: the apparatus of Example 15, wherein the first layer further contacts the substrate.

Example 17: the apparatus of Examples 11-16, wherein the component is a bridge for electrically coupling a first die to a second die.

Example 18: an apparatus, comprising: a substrate; a component embedded in the substrate, wherein the component has a pad on a surface of the component; a protective layer contacting the surface of the component and a portion of the pad; and a via through the substrate and contacting the pad.

Example 19: the apparatus of Example 18, wherein the protective layer contacts a sidewall of the component.

Example 20: the apparatus of Example 18 or Example 19, wherein a portion of the protective layer is embedded in the substrate with a first surface of the protective layer and a second surface of the protective layer both contacting the substrate.

What is claimed is:

1. An apparatus, comprising:
a substrate;
a component in the substrate, wherein the component comprises a pad;
a first layer over the pad, wherein the first layer comprises silicon and nitrogen;
a second layer over the substrate; and
a via that passes through the first layer and the second layer, wherein the via contacts the pad.

2. The apparatus of claim 1, wherein the first layer only contacts the component at the pad.

3. The apparatus of claim 1, wherein the first layer contacts a surface of the component and the pad.

4. The apparatus of claim 1, wherein the first layer contacts a surface of the component, the pad, and a sidewall of the component.

5. The apparatus of claim 4, wherein the first layer contacts the substrate.

6. The apparatus of claim 1, further comprising a cavity in the substrate, wherein the component is within the cavity, and wherein the second layer fills a portion of the cavity and contacts the first layer.

7. The apparatus of claim 1, wherein the component is a bridge configured to provide an electrical connection between a first die and a second die over the substrate.

8. The apparatus of claim 1, wherein the component comprises a via through at least a portion of a thickness of the component.

9. The apparatus of claim 1, wherein the component comprises a glass layer, a dielectric layer, a ceramic layer, or a layer comprising silicon.

10. The apparatus of claim 1, wherein the substrate is electrically coupled to a board, and wherein the component is electrically coupled to a first die and a second die.

11. An apparatus, comprising:
a substrate with a first surface and a second surface opposite from the first surface;
a cavity into the first surface;
a component in the cavity, wherein the component comprises a pad;
a first layer over the component, wherein the first layer contacts at least a portion of the pad;
a second layer over the substrate, wherein the second layer covers the component and fills a portion of the cavity; and
a via through the second layer and the first layer, wherein the via contacts the pad, and wherein the via has a first sidewall with a first angle relative to the first surface of the substrate and a second sidewall with a second angle relative to the first surface of the substrate.

12. The apparatus of claim 11, wherein the first angle is between approximately 80° and approximately 90°, and wherein the first sidewall is through a thickness of the first layer.

13. The apparatus of claim 11, wherein the pad has an average surface roughness (Ra) that is approximately 100 nm or greater.

14. The apparatus of claim 11, wherein the first layer contacts the pad and a surface of the component adjacent to the pad.

15. The apparatus of claim 14, wherein the first layer further contacts a sidewall of the component.

16. The apparatus of claim 15, wherein the first layer further contacts the substrate.

17. The apparatus of claim 11, wherein the component is a bridge for electrically coupling a first die to a second die.

18. An apparatus, comprising:
a substrate;
a component embedded in the substrate, wherein the component has a pad on a surface of the component;
a protective layer contacting the surface of the component and a portion of the pad; and
a via through the substrate and contacting the pad.

19. The apparatus of claim 18, wherein the protective layer contacts a sidewall of the component.

20. The apparatus of claim 18, wherein a portion of the protective layer is embedded in the substrate with a first surface of the protective layer and a second surface of the protective layer both contacting the substrate.
